(19) United States
(12) Patent Application Publication
(10) Pub. No.: US 2019/0137776 A1
(43) Pub. Date: May 9, 2019

(54) METHODS OF MANUFACTURING VERTICAL SEMICONDUCTOR DEVICES

(71) Applicants: Samsung Electronics Co., Ltd., Suwon-si (KR); Korea Advanced Institute Of Science And Technology, Daejeon (KR)

(72) Inventors: Sung-yoon Ryu, Suwon-si (KR); Yu-sin Yang, Seoul (KR); Chung-sam Jun, Suwon-si (KR); Hyun-su Kwak, Daejeon (KR); Jung-won Kim, Daejeon (KR)

(21) Appl. No.: 16/135,640

(22) Filed: Sep. 19, 2018

(30) Foreign Application Priority Data
Nov. 9, 2017 (KR) 10-2017-0148715

(51) Int. Cl. G02B 27/28; G01B 11/06; G21K 1/02; G02B 27/14; G01J 3/02; H01L 21/66

(52) U.S. Cl. CPC G02B 27/283; G01B 11/0625; G21K 1/02; H01L 27/115; G01J 3/0224; G01J 3/0208; H01L 22/12; G02B 27/14

(57) ABSTRACT

Provided are a multilayer structure inspection apparatus and method of inspecting a multilayer structure in a sample without damaging the sample, the multilayer structure inspection apparatus being configured to measure both of reflectance and dispersion without damaging the sample, wherein the reflectance and dispersion are variables which are changed sensitively to a change in a repetitive pattern of the multilayer structure, by measuring values thereof, a structural change of the sample between before and after a process is inspected with high accuracy.

### CROSS-REFERENCE TO RELATED APPLICATION

This application claims priority under 35 U.S.C. § 119 to Korean Patent Application No. 10-2017-0148715, filed on Nov. 9, 2017, in the Korean Intellectual Property Office, the disclosure of which is incorporated herein in its entirety by reference.

### BACKGROUND

The inventive concept relates to an inspection apparatus and an inspection method using the same. For example, the disclosure relates to an inspection apparatus and an inspection method capable of accurately inspecting a multilayer structure in a semiconductor device or during a process of manufacturing a semiconductor device.

Electron microscopes, spectroscopic ellipsometry (SE), spectroscopic reflectometry (SR), etc., are used to inspect a multilayer structure in a semiconductor device or measure the thickness of each layer of the multilayer structure. The electron microscopes are apparatuses for forming a magnified image of an object by using an electron beam and an electron lens. The electron microscopes may solve restrictive resolutions of general optical microscopes, may enable microscopic observation, and thus are used a lot to analyze a semiconductor device. In SE or SR, the thickness of each layer may be measured by comparing a variation in a spectrum of a polarized component reflected from a sample, to a theoretical spectrum obtained through optical simulations, and a variation in the thickness of each layer between before and after a process may be detected without cutting or additionally processing the sample.

### SUMMARY

The present disclosure provides a multilayer structure inspection apparatus and method capable of reliably inspecting a multilayer structure in a sample without damaging the sample. The present disclosure also provides a semiconductor device fabricating method capable of increasing the reliability of a semiconductor device and increasing a yield of a semiconductor device manufacturing process by using the above the multilayer structure inspection apparatus.

According to an aspect of the inventive concept, there is provided a multilayer structure inspection apparatus including an input unit configured to generate a polarized beam, a beam splitter configured to split the polarized beam provided from the input unit, into a first beam and a second beam, a sample unit including a stage configured to support a sample and configured to provide, to the beam splitter, a first reflected beam generated by reflecting the first beam off the sample, a reference unit including a reference mirror and configured to provide, to the beam splitter, a second reflected beam generated by reflecting the second beam off the reference mirror, and a detecting unit configured to detect an intensity of light according to wavelengths by receiving a predetermined polarized component of the first reflected beam or a superposed beam of the first and second reflected beams, the first reflected beam and the superposed beam transmitted through the beam splitter, wherein the multilayer structure inspection apparatus is configured to inspect a multilayer structure of the sample by measuring reflectance and dispersion based on the intensity of light according to wavelengths.

According to another aspect of the inventive concept, there is provided a multilayer structure inspection apparatus including a multi-wavelength light source, a collimator configured to collimate a beam provided from the multi-wavelength light source into a parallel beam, a first polarizer configured to polarize the beam provided from the collimator, a beam splitter configured to split the beam provided from the first polarizer into a first beam and a second beam, a sample unit including a sample translation state configured to support a sample having a multilayer structure, the sample unit configured to provide, to the beam splitter, a first reflected beam generated by reflecting the first beam off the sample, a reference unit including a reference mirror, the reference unit configured to provide, to the beam splitter, a second reflected beam generated by reflecting the second beam off the reference mirror, a second polarizer configured to transmit a predetermined polarized component of the first reflected beam or a superposed beam of the first and second reflected beams, the first reflected beam and the superposed beam transmitted through the beam splitter, a spectrometer configured to split the beam provided from the second polarizer, according to wavelengths, and a detector configured to detect an intensity of light according to wavelengths from the spectrometer, wherein the sample translation stage is configured to move the sample mounted thereon, wherein the reference unit further includes a blocker configured to selectively provide the second beam to the reference mirror, and a blocker translation stage configured to turn on or off the blocker by moving the blocker, and wherein the multilayer structure inspection apparatus is configured to inspect the sample by measuring reflectance and dispersion based on the intensity of light according to wavelengths.

According to another aspect of the inventive concept, there is provided a multilayer structure inspection apparatus including a multi-wavelength light source, a monochromator configured to convert a beam provided from the multi-wavelength light source, into a monochromatic beam, a collimator configured to collimate the monochromatic beam provided from the monochromator into a parallel beam, a first polarizer configured to polarize the parallel beam provided from the collimator, a beam splitter configured to split the polarized beam provided from the first polarizer, into a first beam and a second beam, a sample unit including a sample translation stage configured to support a sample having a multilayer structure, the sample unit configured to provide, to the beam splitter, a first reflected beam generated by reflecting the first beam off the sample, a reference unit including a reference mirror, the reference unit configured to provide, to the beam splitter, a second reflected beam generated by reflecting the second beam off the reference mirror, a second polarizer configured to transmit a predetermined polarized component of the first reflected beam or a superposed beam of the first and second reflected beams, the first reflected beam and the superposed beam transmitted through the beam splitter, and a detector configured to detect an intensity of the beam transmitted from the second polarizer, wherein the sample translation stage is configured to move the sample mounted thereon, wherein the reference unit further includes a blocker configured to selectively provide the second beam to the reference mirror, and a blocker translation stage configured to turn on or off the blocker by moving the blocker, and wherein the multilayer structure inspection apparatus is configured to inspect the sample by measuring reflectance and dispersion based on the intensity of the beam transmitted from the second polarizer according to wavelengths.

According to another aspect of the inventive concept, there is provided a method of inspecting a multilayer structure, the method including inputting a beam to a beam splitter from an input unit, in the beam splitter, splitting the beam provided from the input unit into a first beam and a second beam, generating a first reflected beam by reflecting the first beam off a sample of a sample unit, and generating a second reflected beam by reflecting the second beam off a reference mirror of a reference unit, transmitting the first reflected beam or a superposed beam of the first and second reflected beams through the beam splitter, in a detecting unit, detecting an intensity of light according to wavelengths from the first reflected beam or the superposed beam provided from the beam splitter, and measuring reflectance and dispersion based on the intensity of light according to wavelengths, wherein a multilayer structure of the sample is inspected using one or a combination of the measured reflectance and dispersion.

According to another aspect of the inventive concept, there is provided a method of manufacturing a semiconductor device, the method including inspecting a multilayer structure in a sample wafer based on reflectance and dispersion measured from the sample wafer, determining whether the multilayer structure satisfies a predetermined condition based on an inspection result, and performing a semiconductor device manufacturing process on sample wafer when the multilayer structure of the sample wafer satisfies the predetermined condition, wherein the determining of whether the multilayer structure satisfies the predetermined condition is performed using one or a combination of the measured reflectance and dispersion.

### BRIEF DESCRIPTION OF THE DRAWINGS

Embodiments of the inventive concept will be more clearly understood from the following detailed description taken in conjunction with the accompanying drawings in which:

FIG. 1 is a schematic block diagram of a multilayer structure inspection apparatus according to an embodiment of the inventive concept;

FIGS. 2A and 2B are respectively a block diagram and a conceptual diagram, both illustrating details of the multilayer structure inspection apparatus of FIG. 1;

FIG. 3 is a graph showing reflectance characteristics according to wavelengths of light with respect to different thicknesses of a layer of a multilayer structure in a semiconductor device;

FIG. 4 is a conceptual diagram showing the concept of dispersion by using a dielectric multilayer mirror;

FIGS. 5 and 6 are block diagrams showing operations of reference parts in multilayer structure inspection apparatuses according to embodiments of the inventive concept;

FIG. 7 is a schematic structural diagram of a multilayer structure inspection apparatus according to an embodiment of the inventive concept;

FIG. 8 is a detailed structural diagram of a monochromator of the multilayer structure inspection apparatus of FIG. 7;

FIGS. 9A and 9B are schematic block diagrams of multilayer structure inspection apparatuses according to embodiments of the inventive concept;

FIG. 10 is a flowchart of a multilayer structure inspection method according to an embodiment of the inventive concept;

FIGS. 11 and 12 are flowcharts of multilayer structure inspection methods according to embodiments of the inventive concept; and

FIG. 13 is a flowchart of a semiconductor device fabricating method using a multilayer structure inspection method, according to an embodiment of the inventive concept.

### DETAILED DESCRIPTION

Hereinafter, the inventive concept will be described in detail by explaining embodiments of the inventive concept with reference to the attached drawings. Like reference numerals in the drawings denote like elements and repeated descriptions thereof will be omitted.

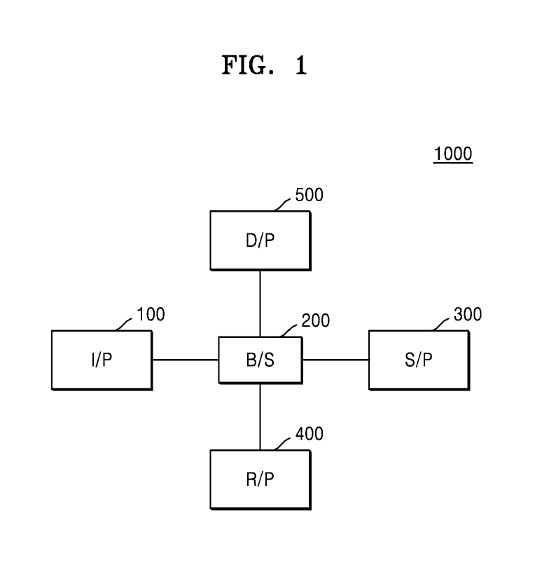

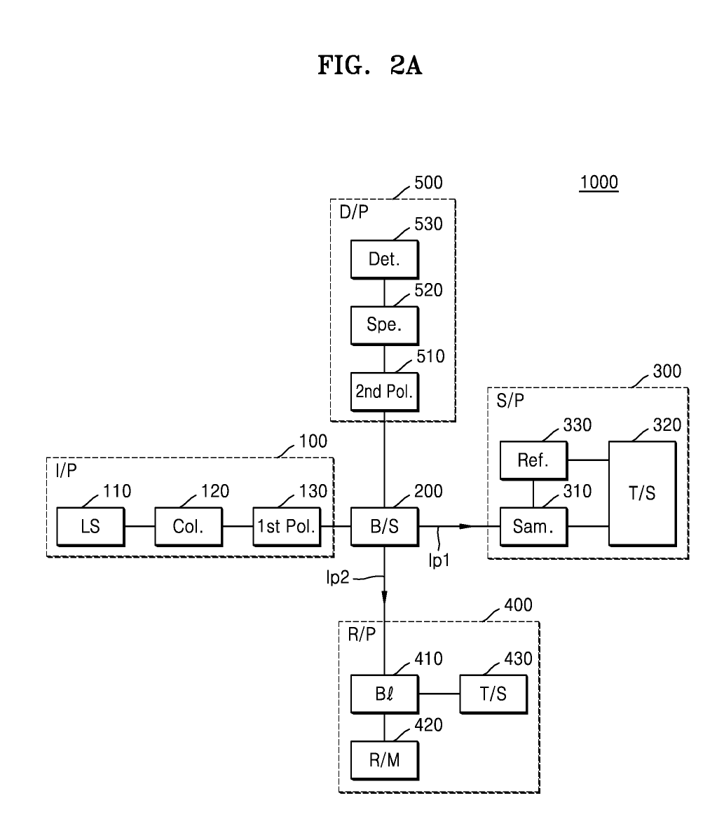

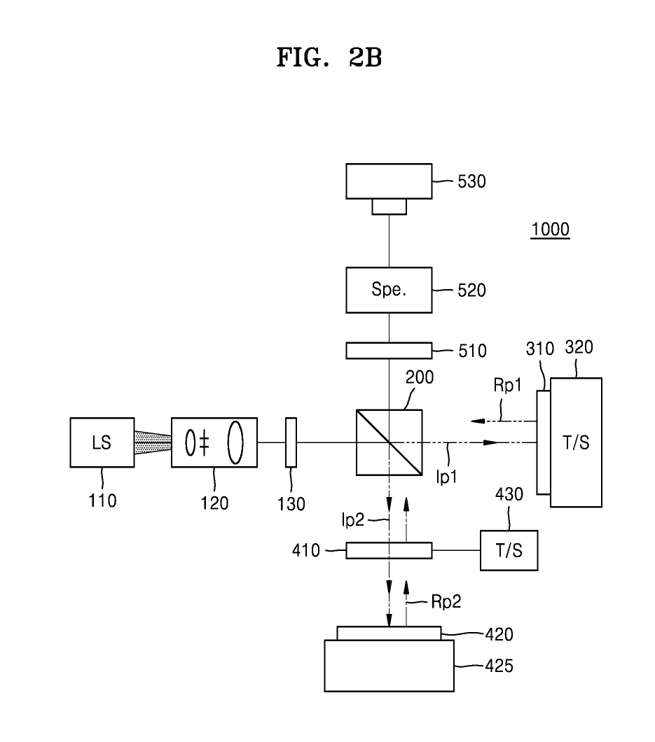

FIG. 1 is a schematic block diagram of a multilayer structure inspection apparatus 1000 according to an embodiment of the inventive concept, and FIGS. 2A and 2B are respectively a block diagram and a conceptual diagram, both illustrating details of the multilayer structure inspection apparatus 1000 of FIG. 1.

Referring to FIGS. 1 to 2B, the multilayer structure inspection apparatus 1000 of the current embodiment may include an input part 100, a beam splitter 200, a sample part 300, a reference part 400, and a detecting part 500. The different “parts” described herein may also be described as units.

As illustrated in FIGS. 2A and 2B, the input part 100 may include a light source 110, a collimator 120, and a first polarizer 130. The light source 110 may be a multi-wavelength light source for generating and outputting a multi-wavelength beam. For example, in the multilayer structure inspection apparatus 1000 of the current embodiment, the light source 110 may generate and output a beam of a band of 170 nm to 2100 nm. By implementing the light source 110 as a multi-wavelength light source, various spectrums may be generated.

The collimator 120 may collimate the beam provided from the light source 110, into a parallel beam and output the parallel beam. The collimator 120 may be implemented as a transmission-type collimator using at least one lens. However, the collimator 120 is not limited thereto and may be implemented as a reflectance-type collimator using, for example, an aspheric mirror.

The first polarizer 130 may polarize the parallel beam provided from the collimator 120. For example, the first polarizer 130 may linearly polarize the incident beam by transmitting and outputting only a p-polarized component (or a horizontal component) or an s-polarized component (or a vertical component) of the incident beam. According to certain embodiments, an iris (e.g., an iris diaphragm) may be positioned between the collimator 120 and the first polarizer 130 to control the intensity of light.

In the multilayer structure inspection apparatus 1000 of the current embodiment, the first polarizer 130 may be implemented as a rotating polarization filter. For example, when the first polarizer 130 is implemented as a rotating polarization filter, the first polarizer 130 may rotate to change a polarized component, e.g., a polarization direction, thereof. As described above, by implementing the first polarizer 130 as a rotating polarization filter, the polarized component may be freely changed and thus measurement variables for reflectance and/or dispersion may be diversified. For example, with a rotating function of the first polarizer 130, the multilayer structure inspection apparatus 1000 may provide more options to measure the correct structure of layers. The diversification of the measurement variables for reflectance and/or dispersion based on the change in the polarized component will be described in detail below in relation to a second polarizer 510.

For example, the input part 100 may generate a multi-wavelength beam, collimate the multi-wavelength beam into a parallel beam, and then input a certain polarized component of the parallel beam to the beam splitter 200.

The beam splitter 200 may split the input beam into a first incident beam Ip1 and a second incident beam Ip2. The beam splitter 200 may spatially split the input beam into the first and second incident beams Ip1 and Ip2. For example, the beam splitter 200 may be a non-polarizing beam splitter and may split the beam regardless of polarization. For example, the beam splitter 200 may split the input beam into the first and second incident beams Ip1 and Ip2 at an intensity ratio of 1:1. For example, the beam splitter 200 may split the input beam into the first and second incident beams Ip1 and Ip2 by transmitting a part of the input beam and reflecting the other part of the input beam.

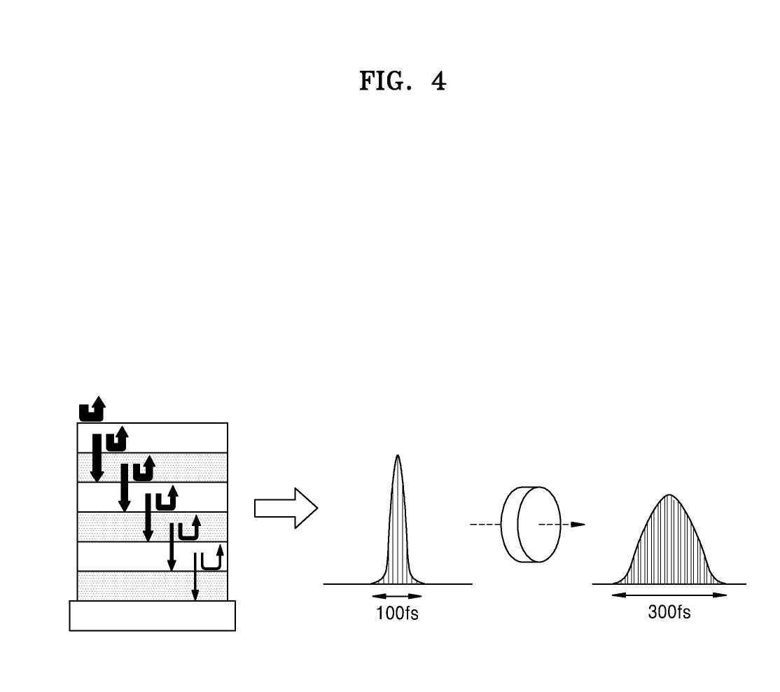

The first incident beam Ip1 corresponding to one of the beams split by the beam splitter 200 may be input to the sample part 300, and the second incident beam Ip2 corresponding to the other of the beams split by the beam splitter 200 may be input to the reference part 400. The beam splitter 200 may enable measurement of dispersion by splitting the input beam to provide the split beams separately to the sample part 300 and the reference part 400 and by superposing beams reflected from the sample part 300 and the reference part 400 to cause interference therebetween. The dispersion will be described in detail below in relation to FIG. 4.

The sample part 300 may include a sample 310, a sample translation stage 320, and a reference sample 330. The sample 310 is an object to be inspected and may include a multilayer structure therein. For example, the sample 310 may be a 3D semiconductor device including a multilayer structure therein, e.g., a vertical-NAND (VNAND) flash memory. However, the type of the sample 310 is not limited to the VNAND flash memory.

For inspection, the sample 310 may be mounted on the sample translation stage 320 and may be supported and moved by the sample translation stage 320. The beam provided from the beam splitter 200, e.g., the first incident beam Ip1, may be incident on the sample 310 and a first reflected beam Rp1 may be generated by the sample 310. As the sample translation stage 320 moves in a direction, the sample 310 may be moved in the direction. Due to the motion of the sample 310 with the sample translation stage 320, a change occurs in a graph related to interference and thus dispersion may be measured and calculated.

The reference sample 330 may be a standard sample for which a multilayer structure therein is verified to be standard or normal. The multilayer structure in the sample 310 corresponding to an object to be inspected may be normal or abnormal. For example, the multilayer structure of the sample 310 may satisfy a predetermined condition (e.g., its product specification) or not. Therefore, it may be determined whether the sample 310 is normal or abnormal (e.g. whether the sample 310 meets the product specification) by inspecting the sample 310 by using the multilayer structure inspection apparatus 1000 of the current embodiment. However, in some cases, when the multilayer structure inspection apparatus 1000 has an error in measuring the sample 310, it may not be accurately determined whether the sample 310 is normal. In this case, the reference sample 330 may be used. For example, instead of the sample 310, the reference sample 330 may be mounted and inspected on the sample translation stage 320 and it may be determined whether the multilayer structure inspection apparatus 1000 has an error, based on the inspection result. For example, the multilayer structure inspection apparatus 1000 of the current embodiment may perform, for example, diagnosis of the state of the multilayer structure inspection apparatus 1000, calibration of a measured spectrum, and compensation of a reference value by inspecting the reference sample 330.

The reference part 400 may include a blocker 410, a reference mirror 420, and a blocker translation stage 430. The blocker 410 may block or transmit the beam provided from the beam splitter 200, e.g., the second incident beam Ip2. For example, when the blocker 410 is turned off, the second incident beam Ip2 provided from the beam splitter 200 is incident on the reference mirror 420 and a second reflected beam Rp2 may be generated by the reference mirror 420. Otherwise, when the blocker 410 is turned on, the second incident beam Ip2 provided from the beam splitter 200 may be blocked by the blocker 410 and thus may not be incident on the reference mirror 420. In this case, the second reflected beam Rp2 may not be generated by the reference mirror 420.

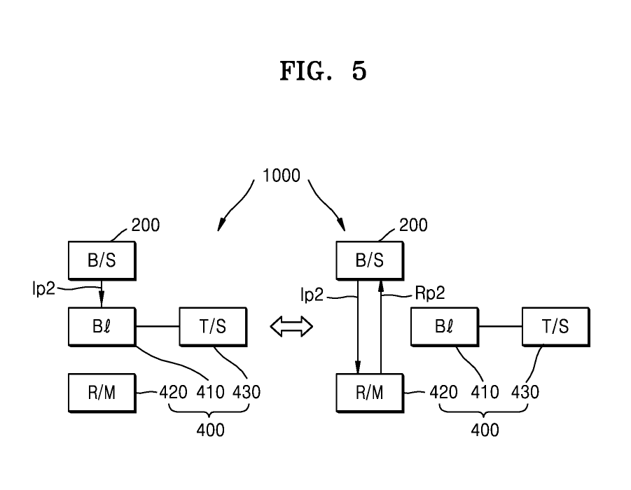

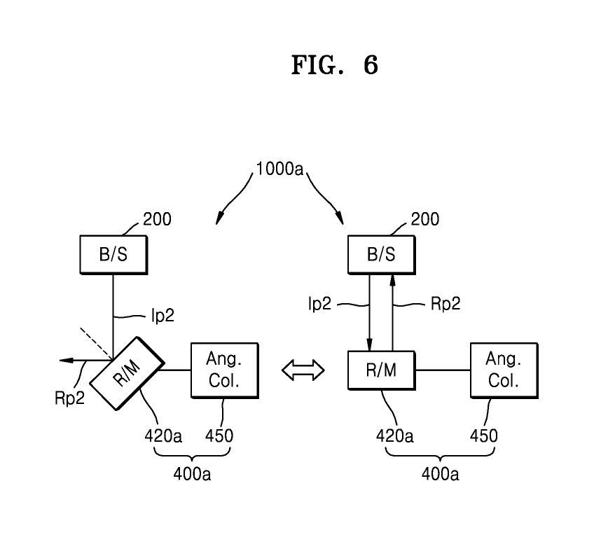

The blocking of the second incident beam Ip2 provided from the beam splitter 200, by the blocker 410 may be performed under the control of the blocker translation stage 430. Various embodiments related to the structure and operation of the blocker 410 will be described in detail below in relation to FIGS. 5 and 6.

The reference mirror 420 generates the second reflected beam Rp2 by reflecting the incident second incident beam Ip2. The reference mirror 420 may generate the second reflected beam Rp2 that interferes with the first reflected beam Rp1 provided from the sample 310, and may provide an unvaried reference reflected beam. For example, the second reflected bean Rp2 may be used as a reference beam of the multilayer structure inspection apparatus 1000. For example, although the first reflected beam Rp1 provided from the sample 310 is changed while the sample 310 is being moved by the sample translation stage 320, since the reference mirror 420 is fixed, the second reflected beam Rp2 provided from the reference mirror 420 may be fixed without being changed.

The detecting part 500 may include a second polarizer 510, a spectrometer 520, and a detector 530. The second polarizer 510 may selectively transmit a certain polarized component of the beam transmitted through the beam splitter 200, e.g., the first reflected beam Rp1 or a beam in which the first reflected beam Rp1 is superposed on the second reflected beam Rp2, i.e., an interfered beam. The second polarizer 510 may be a linear polarizer for transmitting only a certain polarized component of an incident beam and blocking the other components, and may be the same as the above-described first polarizer 130 in terms of function and structure.

According to certain embodiments, a polarizer having a compensation function may be further provided. For example, the compensation function may be a phase compensation of light. For example, the polarizer having the compensation function may include a phase compensation element next to a polarizer, or a phase compensation element may be integrated with a polarizer. For example, without the reference part 400 of the present embodiment, the multilayer structure inspection apparatus 1000 of the current embodiment may compose a spectroscopic ellipsometry (SE) or spectroscopic reflectometry (SR) system. For example, the first polarizer 130 may be referred to as a polarizer P, the polarizer having a compensation function is referred to as a compensator C, the second polarizer 510 may be referred to as an analysis polarizer A, and the sample 310 may be referred to as a sample S. Based on presence and locations of these elements, this apparatus may be classified into a PCSA ellipsometer system, a PSA ellipsometer system, a PSCA ellipsometer system, or a PCSCA ellipsometer system.

The spectrometer 520 may split the beam transmitted through the second polarizer 510 according to wavelengths. For example, the spectrometer 520 may be implemented as a prism or a diffraction grating. The spectrometer 520 may split the incident beam according to wavelengths and provide the split beams to different locations in the detector 530.

The detector 530 may receive the beams split according to wavelengths by the spectrometer 520 and detect a variation in the intensity of light according to wavelengths. The detector 530 may be a multi-channel detector capable of simultaneously measuring beams of multiple wavelengths. For example, the detector 530 may be implemented as a charge coupled device (CCD) or a photodiode array (PDA). As the detector 530 detects the variation in the intensity of light according to wavelengths, reflectance and dispersion of the sample 310 may be measured. Based on the measured reflectance and dispersion of the sample 310, the multilayer structure in the sample 310 may be inspected. Herein, the multilayer structure may be inspected by measuring the thickness of each layer in the multilayer structure or by detecting a defect from at least one layer in the multilayer structure. However, the inspection of the multilayer structure is not limited to the above-described thickness measurement or defect detection.

Operation of the multilayer structure inspection apparatus 1000 of the current embodiment will now be briefly described based on operations of the sample part 300 and the reference part 400. Initially, when the blocker 410 of the reference part 400 operates to block the second incident beam Ip2 and thus the second reflected beam Rp2 is not generated, only the first reflected beam Rp1 provided from the sample 310 may be transmitted through the beam splitter 200 and may be detected by the detector 530, thereby measuring reflectance of the sample 310. Thereafter, when the blocker 410 does not operate and thus the second reflected beam Rp2 is generated and is incident on the beam splitter 200, the second reflected beam Rp2 may be superposed on the first reflected beam Rp1 provided from the sample 310, in the beam splitter 200 to generate an interfered beam and the detector 530 may detect the interfered beam, thereby measuring dispersion of the sample 310.

The multilayer structure inspection apparatus 1000 of the current embodiment may be configured to measure both of the reflectance and dispersion without damaging the sample 310. The reflectance and dispersion may be variables which are changed sensitively to a change in a repetitive pattern of the multilayer structure. By measuring values thereof, a structural change of the sample 310 between before and after a process may be inspected with high accuracy and/or consistency.

In certain embodiments of inspection apparatuses, an apparatus for measuring reflectance may be separated from an apparatus for measuring dispersion and each apparatus may not include an additional apparatus for calibration in the dispersion or reflectance measurement process. For example, repeated measurement of a certain location in a sample wafer may not be performed. For example, when the reflectance and dispersion are simultaneously used, the data of the same location may not coincide due to switching of inspection apparatuses.

In the multilayer structure inspection apparatus 1000 of the current embodiment, since a single apparatus may measure both of reflectance and dispersion, both of the reflectance data and the dispersion data may be stably obtained with respect to the same location of the sample 310. For example, by checking the state of the multilayer structure inspection apparatus 1000 before and/or after the sample 310 is measured and/or by implementing an additional mode of measuring the reference sample 330 to compensate a reference value (or offset) from which the measured data may be calculated, repeatability and reliability of the data may be enhanced. Herein, the state of the multilayer structure inspection apparatus 1000 may include an alignment error of the multilayer structure inspection apparatus 1000, a change in characteristics of the multilayer structure inspection apparatus 1000, etc. Therefore, the state of the multilayer structure inspection apparatus 1000 may be monitored in real time by using the mode of measuring the reference sample 330.

In the multilayer structure inspection apparatus 1000 of the current embodiment, a measurement mode may be implemented to be sensitive to a certain variable, e.g., a certain polarized component (or certain polarization direction of light) by mounting the additional first and second polarizers 130 and 510 on the input part 100 and the detecting part 500 respectively. For example, when a beam having a polarized component, e.g., a polarized light beam, is reflected from the sample 310, reflectance of the light may depend on the component of the polarized light (e.g., reflectance of p-wave may be different from reflectance of s-wave) and the phase of the light may be changed in accordance with the polarized component (e.g., p-wave or s-wave). In addition, a polarization direction of the beam incident on the sample 310 may be changed by changing a polarization angle of the first polarizer 130 of the input part 100, and a polarization direction of the beam reflected from the sample 310 and incident on the detector 530 may be changed by changing a polarization angle of the second polarizer 510 of the detecting part 500.

When a profile of a pattern is changed at a measurement location due to a change in a process or occurrence of a defect, the reflectance and the phase value of the sample 310 are changed. In this case, the tendency of the change in the profile of the pattern may be more clearly detected by changing or adjusting the polarization angles of the first and second polarizers 130 and 510. When the measured sample 310 has a complicated structure, since a variation of each variable in the measurement region influences the reflectance and the phase of the first reflected beam Rp1, a set or a combination of the polarization angles of the first and second polarizers 130 and 510, which influences the variation of each variable and/or the incident beam on the detector 530 most sensitively, may be obtained. Therefore, for a sample including a multilayer structure and/or repeatedly formed layers, e.g., VNAND flash memory, various and independent measurement variables for measuring the thickness of each layer may be obtained by using the first and second polarizers 130 and 510, and thus accuracy or consistency in the measurement of the thickness of each layer may be increased.

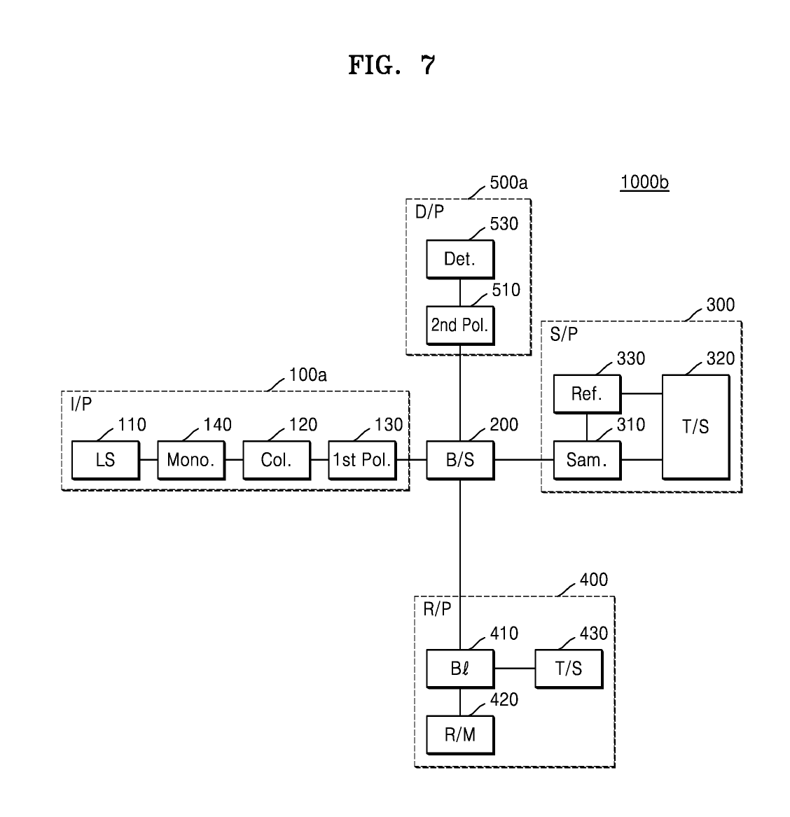

In the multilayer structure inspection apparatus 1000 of the current embodiment, the spectrometer 520 capable of modulating a wavelength frequency to measure reflectance and dispersion according to wavelengths may be included in the detecting part 500. The spectrometer 520 may not be mechanically driven to rapidly measure reflectance and dispersion at a point of the sample 310. For example, the spectrometer 520 may not move during a measurement. For example, the spectrometer 520 may be firmly fixed in the detecting part 500. In this case, a beam of all wavelengths emitted from the light source 110 may be incident on the sample 310, the spectrometer 520 may split the beam reacted with (e.g., reflected from) the sample 310 according to frequencies, and then the detector 530 may receive the split beams, thereby obtaining characteristics of individual frequencies based on a change in characteristics per frequency. In certain embodiments, a monochromator may be used instead of the spectrometer 520 to measure the reflectance and dispersion according to wavelengths, and an embodiment including the monochromator will be described in detail below in relation to FIGS. 7 to 9B.

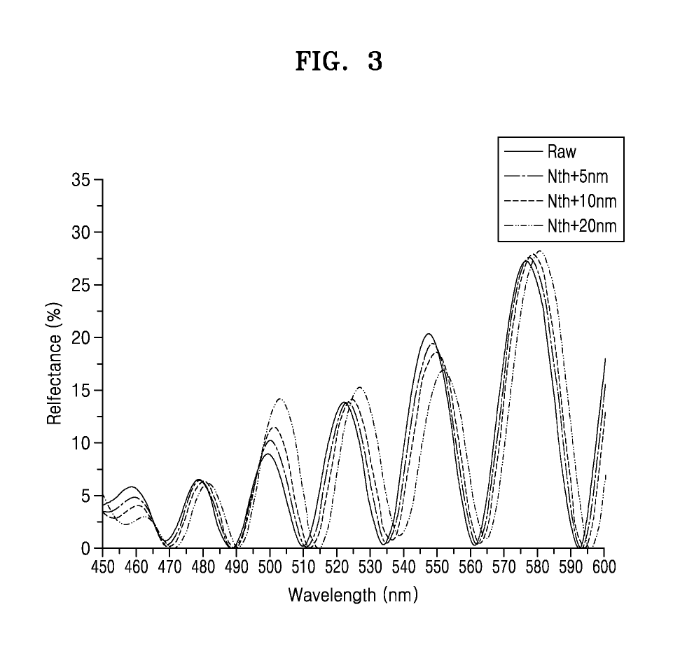

FIG. 3 is a graph showing reflectance characteristics according to wavelengths of light with respect to different thicknesses of a layer of a multilayer structure in a semiconductor device, wherein the x axis indicates the wavelength and the y axis indicates the reflectance.

Referring to FIG. 3, it is shown that the reflectance varies depending on the wavelength and is changed in accordance with a thickness variation of each layer. For example, compared to a raw sample (e.g., a reference sample), when the thickness of an Nth layer in a sample is increased by 5 nm (Nth+5 nm), 10 nm (Nth+10 nm), and 20 nm (Nth+20 nm), the reflectance is changed. Therefore, the thickness of each layer in the multilayer structure may be quantified into a reflectance graph, e.g., through simulations. For example, the thickness of each layer may be measured by comparing a measured reflectance to the quantified reflectance and analyzing the comparison result. The measured reflectance may be a reflectance graph according to wavelengths, which is measured by an inspection apparatus, and the quantified reflectance may be a reflectance graph according to wavelengths, which may be calculated through simulations.

For example, after a database is built with reflectance graphs of a huge number of multilayer structures, a reflectance graph of a sample may be obtained using an inspection apparatus, and then the obtained reflectance graph may be compared to the reflectance graphs in the database to extract a similar graph, thereby inspecting a multilayer structure in the sample. For example, the multilayer structure may be inspected by measuring the thickness of or by detecting a defect from each layer in the multilayer structure. The database of the reflectance graphs may be constructed, e.g., using simulations, and a scanning electron microscope (SEM) or a transmission electron microscope (TEM) using an electron microscope may be used for data verification of the database.

FIG. 4 is a conceptual diagram showing the concept of dispersion by using a dielectric multilayer mirror.

Referring to FIG. 4, dispersion refers to a phenomenon where light waves spread because their velocities vary depending on their wavelengths, and may refer to a degree of the spread of light waves. For example, in a beam of visible light, a shorter wave has a lower velocity than a longer wave, and thus a prism may spread (disperse) the visible light based on colors of light to view a spectrum.

As shown in the left side of FIG. 4, when a beam is incident on a dielectric multilayer mirror, a part of the beam is transmitted through and the other part of the beam is reflected off an interface of each layer. As shown in the right side of FIG. 4, when the beam is transmitted through the dielectric multilayer mirror, dispersion may occur. For example, a beam having a dispersion of about 100 fs before transmitting through the dielectric multilayer mirror may have a dispersion of about 300 fs after transmitting through the dielectric multilayer mirror. When the thickness of a thin film in the dielectric multilayer mirror varies, the dispersion may change. The performance of the dielectric multilayer mirror may be optimized by controlling the thickness of the thin film by using a multilayer analysis method and a dispersion measuring apparatus.

Dispersion may be expressed using femtoseconds (fs) or the square thereof (fŝ2) in the time domain, and such an ultra-small time may not be easily directly measured using a time measuring apparatus. As such, a dispersion may be indirectly measured by using interference. For example, an interfered beam may be obtained by superposing a reference beam reflected from a reference mirror on a sample beam reflected from a sample. The interfered beam may have a certain form of intensity due to constructive interference and/or destructive interference between wavelengths of the reference beam and wavelengths of the sample beam. The form of the interfered beam is changed when the sample is minutely moved, and dispersion may be calculated by matching the amount of motion of the sample to the form of the interfered beam. For example, when the sample beam has a certain dispersion and two wavelengths thereof are spread, and the reference beam is rarely spread and thus two wavelengths thereof corresponding to the two wavelengths of the sample beam nearly coincide, by moving the sample, constructive interference may occur between the reference beam and each wavelength of the sample beam and the distance by which the sample moves between the two constructive interferences may be converted into time difference to calculate the dispersion of the sample beam.

Similarly to a reflectance graph, a dispersion graph varies depending on, for example, the thickness of each layer in a multilayer structure and is changed in accordance with a thickness variation of each layer. Therefore, similarly to a reflectance graph, the thickness of each layer in the multilayer structure may be quantified into a dispersion graph e.g., through simulations, and the thickness of each layer may be measured by comparing a dispersion graph measured using an inspection apparatus, to the dispersion graph, e.g., calculated through simulations, and then analyzing the comparison result. For example, after a database is built with dispersion graphs of a huge number of multilayer structures, a dispersion graph of a sample may be obtained using an inspection apparatus, and then the obtained dispersion graph may be compared to the dispersion graphs in the database to extract a similar graph, thereby inspecting a multilayer structure in the sample.

As described above, the multilayer structure inspection apparatus 1000 (see FIG. 1) of the current embodiment may measure both of reflectance and dispersion of the sample 310 without switching apparatuses. Therefore, accuracy or consistency in measurement and reliability of analysis may be increased by inspecting the multilayer structure in the sample 310 by using the measured reflectance or dispersion, or both.

FIGS. 5 and 6 are block diagrams showing operations of reference parts 400 and 400a in respective multilayer structure inspection apparatuses 1000 and 1000a according to embodiments of the inventive concept. Descriptions of elements similar to or the same as the ones described above in relation to FIGS. 1 to 2B will be briefly provided or omitted herein. For example, omitted elements in the description and/or in the FIGS. 5 and 6 of the present embodiments may be the same as corresponding elements of previous embodiments.

Referring to FIG. 5, as described above, in the multilayer structure inspection apparatus 1000 of the current embodiment, blocking of the second incident beam Ip2 by the blocker 410 may be performed under the control of the blocker translation stage 430. For example, as shown in the left side of FIG. 5, when the blocker 410 is turned on, e.g., when the blocker 410 is positioned between the beam splitter 200 and the reference mirror 420, the second incident beam Ip2 provided from the beam splitter 200 may be blocked by the blocker 410 and thus a second reflected beam may not be generated by the reference mirror 420. Otherwise, as shown in the right side of FIG. 5, when the blocker 410 is turned off, e.g., when the blocker 410 is eliminated from between the beam splitter 200 and the reference mirror 420, the second incident beam Ip2 provided from the beam splitter 200 may be incident on the reference mirror 420 and the second reflected beam Rp2 may be generated by the reference mirror 420.

For example, the blocker 410 may be made of a light-absorbing material. As such, the second incident beam Ip2 provided from the beam splitter 200 may be absorbed by the blocker 410. Alternatively, the blocker 410 may reflect the second incident beam Ip2. However, the blocker 410 may block the second incident beam Ip2 from being incident on the reference mirror 420 by reflecting the second incident beam Ip2 outside the beam splitter 200 and/or the reference mirror 420.

Referring to FIG. 6, the multilayer structure inspection apparatus 1000a of the current embodiment may differ from the multilayer structure inspection apparatus 1000 of FIG. 5 in the configuration of the reference part 400a. For example, in the multilayer structure inspection apparatus 1000a of the current embodiment, the reference part 400a may include a reference mirror 420a and an angle controller 450. The reference mirror 420a may generate the second reflected beam Rp2 by reflecting the second incident beam Ip2 provided from the beam splitter 200. However, an angle of the reference mirror 420a may be changed by the angle controller 450.

For example, as shown in the left side of FIG. 6, a top surface of the reference mirror 420a may be tilted by the angle controller 450 at a certain angle from the second incident beam Ip2. Therefore, the second reflected beam Rp2 generated by the reference mirror 420a does not proceed toward the beam splitter 200. Otherwise, as shown in the right side of FIG. 6, the reference mirror 420a may be horizontally positioned by the angle controller 450 in such a manner that the top surface of the reference mirror 420a is perpendicular to the second incident beam Ip2, and thus the second reflected beam Rp2 generated by the reference mirror 420a may proceed toward the beam splitter 200.

As described above, in the multilayer structure inspection apparatus 1000a of the current embodiment, the angle controller 450 may serve as the blocker 410 of the multilayer structure inspection apparatus 1000 of FIG. 5 by controlling the angle of the reference mirror 420a. For example, by tilting the reference mirror 420a in such a manner that the second reflected beam Rp2 does not proceed toward the beam splitter 200 as shown in the left side of FIG. 6, only the first reflected beam Rp1 (see FIG. 2B) provided from the sample 310 of the sample part 300 may be transmitted through the beam splitter 200 and be detected by the detecting part 500. Otherwise, by horizontally positioning the reference mirror 420a as shown in the right side of FIG. 6, an interfered beam in which the first reflected beam Rp1 is superposed on the second reflected beam Rp2 may be transmitted through the beam splitter 200 and be detected by the detecting part 500.

Although two types of reference parts 400 and 400a are described above, the reference part is not limited thereto. For example, various reference parts for blocking the second incident beam Ip2 not to proceed toward the reference mirror 420, not generating a second reflected beam by the reference mirror 420, and/or blocking the second reflected beam generated by the reference mirror 420 not to proceed toward the beam splitter 200 may be used in the multilayer structure inspection apparatus 1000 or 1000a of the current embodiment.

FIG. 7 is a schematic structural diagram of a multilayer structure inspection apparatus 1000b according to an embodiment of the inventive concept, and FIG. 7 illustrates present embodiment in a similar manner to FIG. 2A. The descriptions of elements given above in relation to FIGS. 1 to 2B, 5, and 6 may be applied to corresponding elements of the present embodiment and will be briefly provided or omitted herein.

Referring to FIG. 7, the multilayer structure inspection apparatus 1000b of the current embodiment may differ from the multilayer structure inspection apparatus 1000 of FIG. 2A in that a monochromator 140 is used instead of a spectrometer. For example, in the multilayer structure inspection apparatus 1000b of the current embodiment, an input part 100a may further include the monochromator 140 between the light source 110 and the collimator 120, and a detecting part 500a may not include a spectrometer.

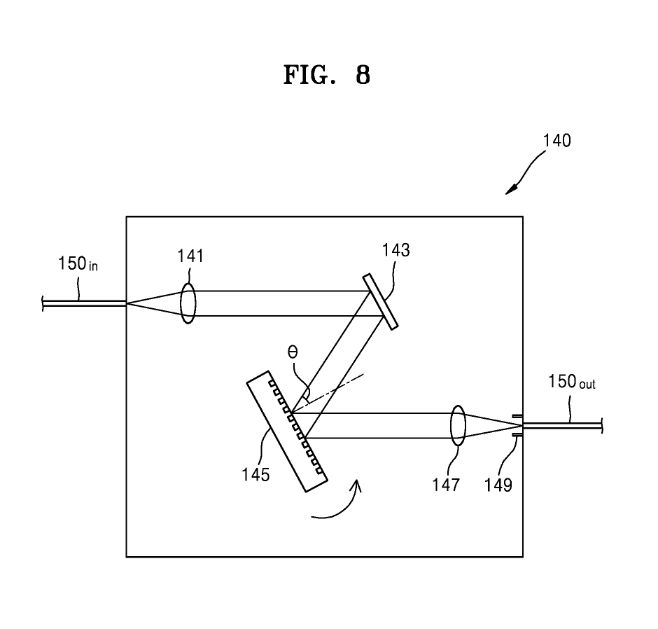

The monochromator 140 may convert a multi-wavelength beam provided from the light source 110, into a monochromatic beam and output the monochromatic beam. Herein, the monochromatic beam may be a single-wavelength beam having a very narrow wavelength bandwidth. For example, the monochromatic beam may be a beam having a wavelength bandwidth of several nm. According to certain embodiments, the monochromator 140 may output not only a monochromatic beam of a single wavelength region but also monochromatic beams of multiple wavelength regions. For example, the monochromator 140 may output a plurality of monochromatic beams in a certain wavelength range. For example, the monochromator 140 may output multiple monochromatic beams while sweeping through a certain wavelength range with a set/predetermined wavelength bandwidth. The structure of the monochromator 140 will be described in detail below in relation to FIG. 8.

The multilayer structure inspection apparatus 1000b of the current embodiment may modulate the multi-wavelength beam into a single-wavelength beam having a certain desired wavelength or wavelength band by using the monochromator 140 located in back of the light source 110, and provide the single-wavelength beam to the sample 310 to measure reflectance and dispersion of light. For example, the monochromator 140 may be positioned between the light source 110 and the collimator 120. When the monochromator 140 is used, the intensity of light of a reflected beam and the intensity of light of an interfered beam at a single wavelength may be separately obtained by the operation of the blocker 410. As such, uniformity of the beam incident on the sample 310 may be enhanced and reflectance and dispersion of light may be measured from a broad region of the sample 310. In certain embodiments, reflectance and dispersion of light with a broad range of wavelengths may be obtained by combining information of the beams of the individual wavelengths split by the monochromator 140.

FIG. 8 is a detailed structural diagram of the monochromator 140 of the multilayer structure inspection apparatus 1000b of FIG. 7.

Referring to FIG. 8, the monochromator 140 may include a collimator 141, a mirror 143, a grating 145, a condenser lens 147, and a slit 149. As described above, the monochromator 140 may convert a multi-wavelength beam provided from the light source 110 (see FIG. 7), into a monochromatic beam and output the monochromatic beam.

The collimator 141 may collimate a beam incident through a first optical fiber 150in, into a parallel beam, and the mirror 143 may provide the beam to the grating 145 at a certain incidence angle θ by reflecting the beam to change a path thereof. The grating 145 may be a device for extracting a monochromatic beam and may split and reflect the incident beam according to wavelengths. For example, the grating 145 may split the incident beam into a plurality of narrow bands of wavelengths, and reflect a selected narrow band of wavelengths to a selected direction and/or location to produce a monochromatic beam. The wavelength of the beam reflected by the grating 145 to a certain location may vary depending on an angle of the beam incident on the grating 145, i.e., the incidence angle θ. For example, on a surface of the grating 145, the narrow bands of wavelengths may reflect different directions from each other depending on respective wavelengths of the narrow bands. This may be because of optical characteristics in which a reflection angle of a primary maximum of a diffraction light may depend on a wavelength of the beam. Therefore, the wavelength of the monochromatic beam reflected to the certain location may be changed by rotating the grating 145 as indicated by an arrow in FIG. 8 to change the incidence angle θ of the beam.

The condenser lens 147 may be positioned at the certain location with respect to the grating 145, and a monochromatic beam desired to be extracted among the beams split according to wavelengths by the grating 145 may be incident on the condenser lens 147. The incident monochromatic beam may be concentrated by the condenser lens 147 and may be incident on a second optical fiber 150out through the slit 149. As described above, the split beams of other wavelengths may be incident on the condenser lens 147 by rotating the grating 145. Therefore, the monochromatic beams of other wavelengths may be concentrated and output through the condenser lens 147 by rotating the grating 145. A concave mirror may be used instead of the condenser lens 147. When the concave mirror is used, a path of the beam may be changed and thus the locations of the slit 149 and the second optical fiber 150out may be changed. While FIG. 8 illustrates a reflective grating 145, in certain embodiments, a transmissive grating may be used instead of the reflective grating 145. In this case, the positions of the components of the monochromator 140 may be rearranged accordingly to adjust the path of the beam thereby providing a proper monochromatic beam.

Instead of the grating 145, a prism may be used to split the incident beam according to wavelengths. When a prism is used, the wavelength of the monochromatic beam output through the condenser lens 147 may be changed by changing the location of the condenser lens 147 without changing the incidence angle. The monochromator 140 may not be coupled to the first and second optical fibers 150in and 150out but may directly receive the multi-wavelength beam from the light source 110, and may directly output the monochromatic beam to the collimator 120.

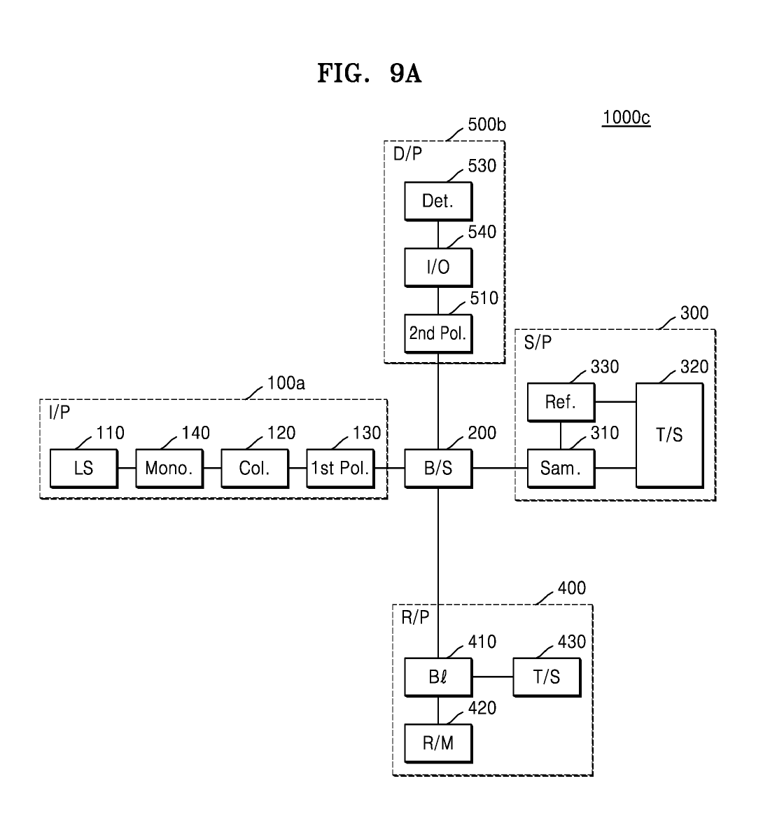

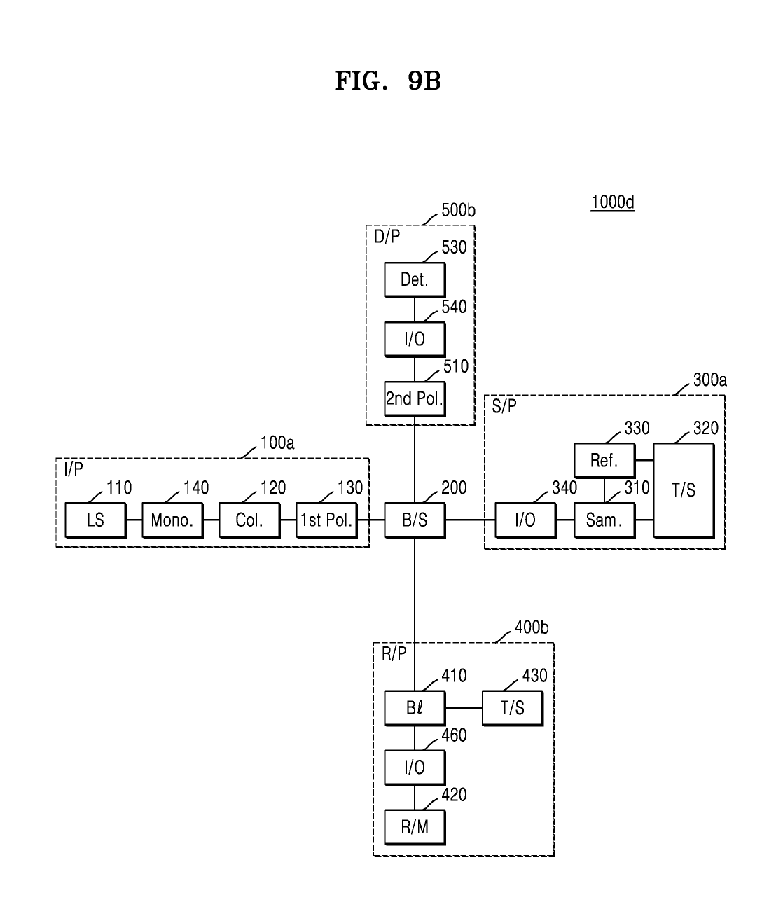

FIGS. 9A and 9B are schematic block diagrams of multilayer structure inspection apparatuses 1000c and 1000d according to embodiments of the inventive concept. The descriptions of elements given above in relation to FIGS. 1 to 2B and 5 to 8 may be applied to corresponding elements of the present embodiment, and will be briefly provided or omitted herein.

Referring to FIG. 9A, the multilayer structure inspection apparatus 1000c of the current embodiment may differ from the multilayer structure inspection apparatus 1000b of FIG. 7 in the configuration of a detecting part 500b. For example, in the multilayer structure inspection apparatus 1000c of the current embodiment, the detecting part 500b may include a first imaging optics 540.

The first imaging optics 540 may form an image on the detector 530 by providing a beam provided from the second polarizer 510 to the detector 530. The image formed on the detector 530 may be related to reflectance and dispersion of the beam reflected off the sample 310. For example, based on enhanced uniformity of the beam through the monochromator 140, an image related to reflectance and dispersion according to wavelengths for a broad region of the sample 310 may be obtained using the first imaging optics 540. The first imaging optics 540 may include, for example, an object lens, a mirror, and a tube lens.

According to certain embodiments, the first imaging optics 540 may be implemented as a low-magnification optics. The low-magnification optics may be an imaging optics for forming light into an image at an equal magnification or a low magnification. For example, the magnification ratio of the low magnification may be from 1:1 to 1:100 (e.g., the resulted image is 100 times of object). A magnification ratio higher than 1:100 may be defined as a high magnification. Since a low-magnification optics is used in the first imaging optics 540, the multilayer structure inspection apparatus 1000c of the current embodiment may have a wide field of view (FOV) and may perform defect detection at a high speed compared to existing SE systems. For example, when a low-magnification optics of 1:100 ratio has an FOV corresponding to an area of A/100, at least 100 shots may be required to inspect the entirety of the sample 310 having an area of A. On the other hand, a low-magnification optics of 1:10 ratio has an FOV corresponding to an area of A, and thus a single shot may be sufficient to inspect the entirety of the sample 310 having an area of A.

Referring to FIG. 9B, the multilayer structure inspection apparatus 1000d of the current embodiment may differ from the multilayer structure inspection apparatus 1000c of FIG. 9A in the configurations of a sample part 300a and a reference part 400b. For example, in the multilayer structure inspection apparatus 1000d of the current embodiment, the sample part 300a may further include a second imaging optics 340 positioned in front of the sample 310. For example, the second imaging optics 340 may be positioned for the first incident beam Ip1 to go through the second imaging optics 340 before the first incident beam Ip1 reaches the sample 310. The reference part 400b may further include a third imaging optics 460 positioned in front of the reference mirror 420. For example, the third imaging optics 460 may be positioned for the second incident beam Ip2 to go through the third imaging optics 460 before the second incident beam Ip2 reaches the reference mirror 420. Since the sample part 300a and the reference part 400b include the second and third imaging optics 340 and 460 respectively, the first and second reflected beams Rp1 and Rp2 may be clearly imaged. For example, the second and third imaging optics 340 and 460 may be helpful for the multilayer structure inspection apparatus 1000d to obtain a clear image by collimating and/or adjusting beams passing therethrough. The above descriptions of the first imaging optics 540 in the multilayer structure inspection apparatus 1000c of FIG. 9A may be equally applied to the second and third imaging optics 340 and 460. For example, the structures and functions of the second and third imaging optics 340 and 460 may be similar to or the same as the structure and function of the first imaging optics 540 of the multilayer structure inspection apparatus 1000c of FIG. 9A.

Although the third imaging optics 460 of the reference part 400b is positioned between the blocker 410 and the reference mirror 420, according to certain embodiments, the third imaging optics 460 may be positioned between the blocker 410 and the beam splitter 200.

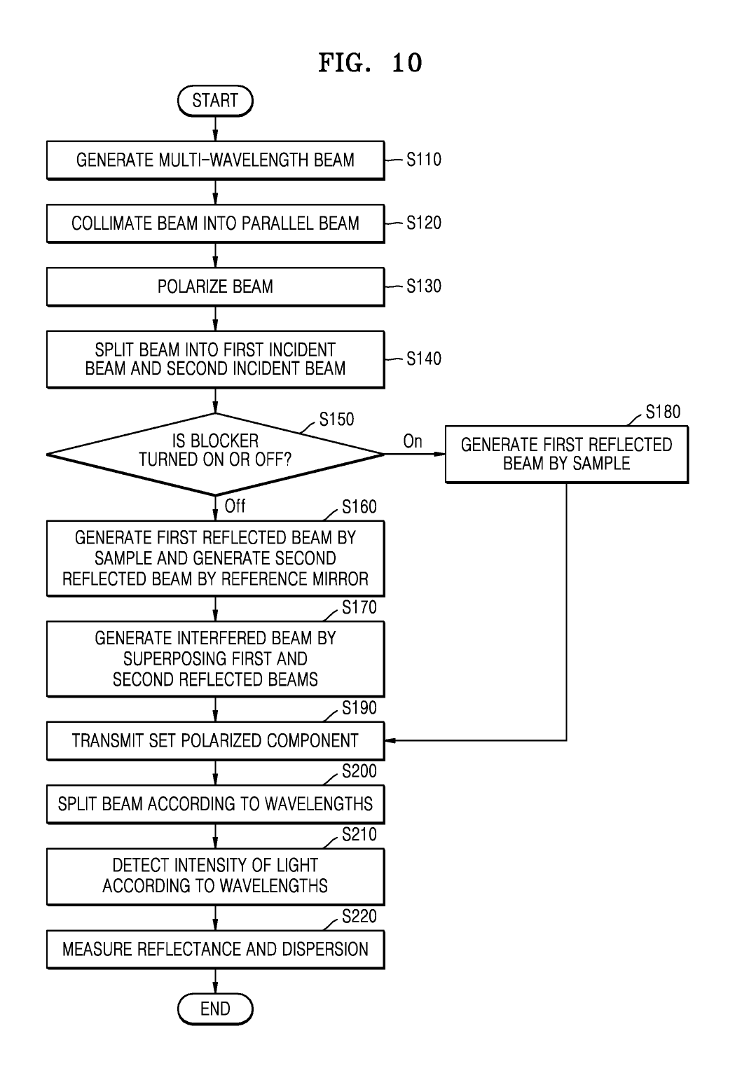

FIG. 10 is a flowchart of a multilayer structure inspection method according to an embodiment of the inventive concept. FIG. 10 will be described in connection with FIGS. 1 to 2B, and the descriptions given above in relation to FIGS. 1 to 2B will be briefly provided or omitted herein.

Referring to FIG. 10, initially, the light source 110 generates a multi-wavelength beam (S110). Thereafter, the collimator 120 collimates the beam provided from the light source 110, into a parallel beam (S120), and then the first polarizer 130 polarizes the beam provided from the collimator 120, to an arbitrary polarization state (S130). The polarization state may be freely changed based on a command input from outside, and thus the first polarizer 130 may be set to an optimal polarization angle to analyze required characteristics.

The beam splitter 200 splits the polarized beam provided from the first polarizer 130, into the first and second incident beams Ip1 and Ip2 (S140). The first incident beam Ip1 may be incident on the sample part 300, and the second incident beam Ip2 may be incident on the reference part 400.

It is determined whether the blocker 410 of the reference part 400 is turned on or off (S150). When the blocker 410 is turned on, e.g., when the blocker 410 blocks the second incident beam Ip2 from being incident on the reference mirror 420, a second reflected beam is not generated by the reference mirror 420 and only the first reflected beam Rp1 is generated by the sample 310 (S180). The first reflected beam Rp1 may be incident on the second polarizer 510 through the beam splitter 200.

Otherwise, when the blocker 410 is turned off, e.g., when the blocker 410 does not block the second incident beam Ip2 and thus the second incident beam Ip2 is incident on the reference mirror 420, the second reflected beam Rp2 is generated by the reference mirror 420 and the first reflected beam Rp1 is generated by the sample 310 (S160).

The beam splitter 200 generates an interfered beam by superposing the first and second reflected beams Rp1 and Rp2 (S170). The interfered beam may be incident on the second polarizer 510.

Then, the second polarizer 510 transmits only a set/predetermined polarized component of the first reflected beam Rp1 or the interfered beam of the first and second reflected beams Rp1 and Rp2 (S190). The spectrometer 520 splits the beam provided from the second polarizer 510, according to wavelengths (S200). The detector 530 detects the intensity of light according to wavelengths from the beams provided from the spectrometer 520 (S210). Thereafter, reflectance and dispersion of the sample 310 are measured based on the detected intensity of light according to wavelengths (S220).

Subsequently, the thickness of each layer of a multilayer structure in the sample 310 may be measured/determined or a defect of the layer may be detected by comparing the measured reflectance and dispersion of the sample 310 to reflectance and dispersion information calculated through simulations, and then analyzing the comparison result. For example, a database in which reflectance and dispersion graphs of a huge number of multilayer structures are accumulated may be used. For example, reflectance and dispersion graphs of the sample 310, which are obtained using the multilayer structure inspection apparatus 1000 of the current embodiment, may be compared to the reflectance and dispersion graphs in the database to extract similar graphs, thereby inspecting the multilayer structure in the sample 310, e.g., determining thicknesses of layers and/or whether there is a defect in the sample 310.

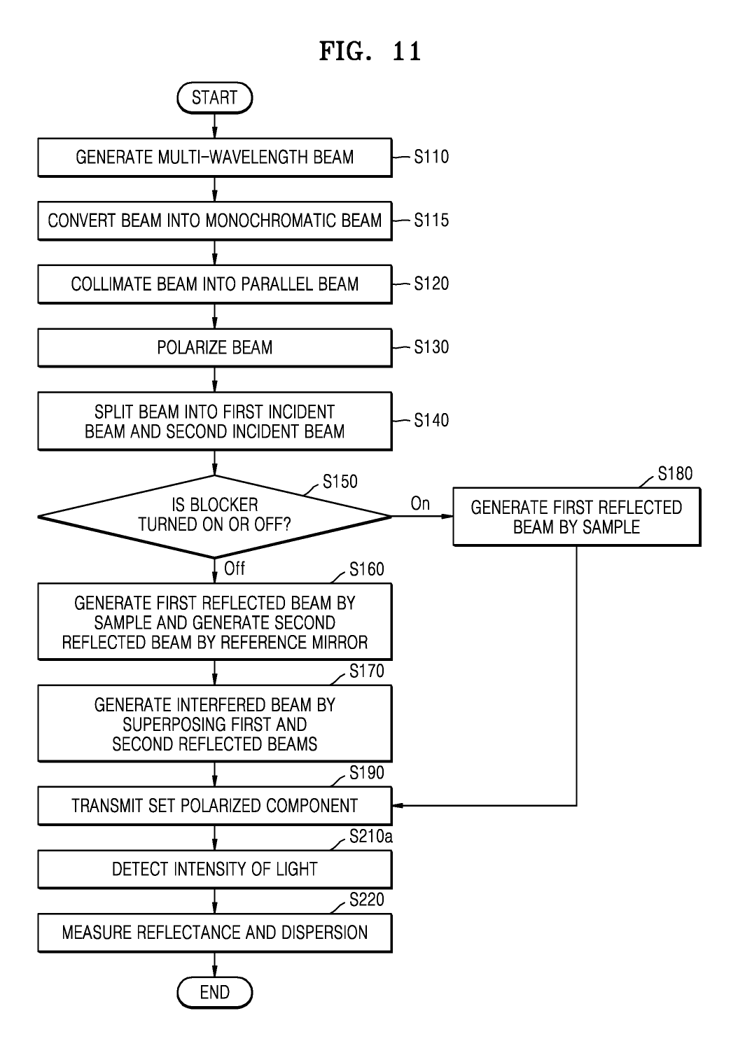

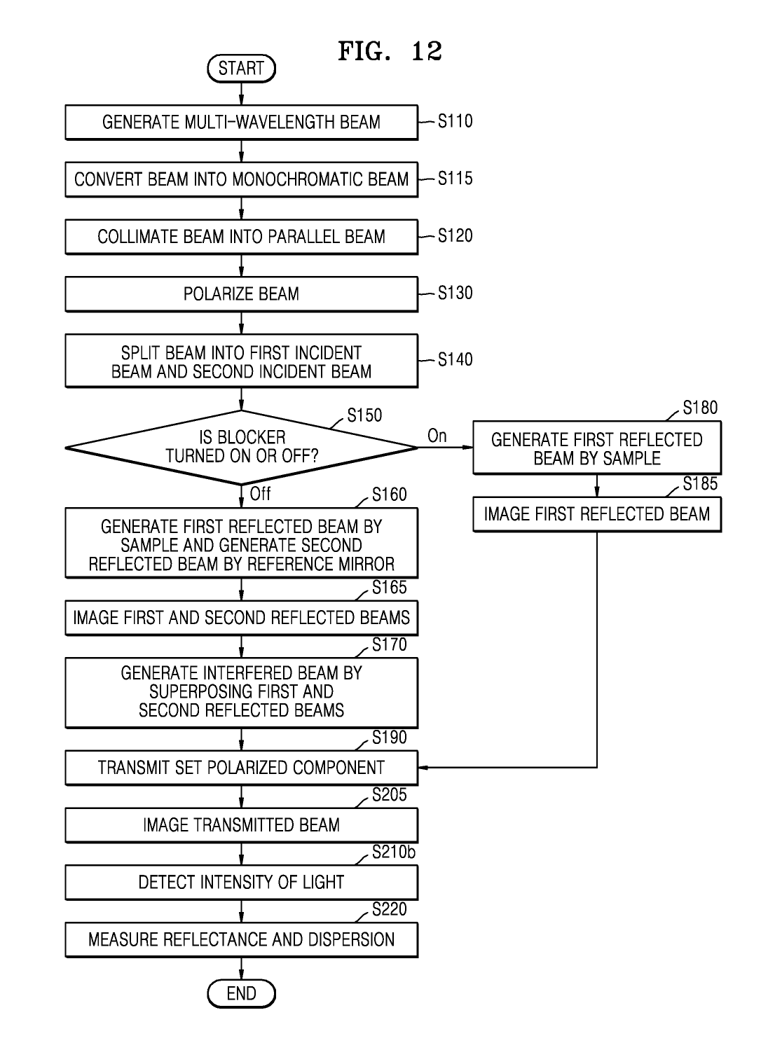

FIGS. 11 and 12 are flowcharts of multilayer structure inspection methods according to embodiments of the inventive concept. FIGS. 11 and 12 will be described in connection with FIGS. 7 to 9B, and the descriptions given above in relation to FIGS. 7 to 9B and 10 will be briefly provided or omitted herein.

Referring to FIG. 11, initially, the light source 110 generates a multi-wavelength beam (S110). Thereafter, the monochromator 140 converts the multi-wavelength beam provided from the light source 110 into a monochromatic beam (S115). The collimator 120 collimates the beam provided from the monochromator 140 into a parallel beam (S120).

Then, operations from an operation of polarizing the beam to an arbitrary polarization state (S130) to an operation of transmitting only a set/predetermined polarized component of the first reflected beam Rp1 or the interfered beam of the first and second reflected beams Rp1 and Rp2 (S190) are performed in a way similar to or the same as the ones described above in relation to FIG. 10.

The beam transmitted through the second polarizer 510 is the monochromatic beam converted by the monochromator 140 and thus does not need to be additionally split by the spectrometer 520. Therefore, the detector 530 detects the intensity of light of the monochromatic beam provided from the second polarizer 510 (S210a). For example, the monochromator 140 may convert the multi-wavelength beam into monochromatic beams according to wavelengths and the detector 530 may detect and combine the monochromatic beams according to wavelengths, thereby detecting the intensity of light according to wavelengths. For example, different monochromatic beams having respective wavelengths may be detected by the detector 530 and the detected monochromatic beams may be combined to determine intensities throughout a predetermined light spectrum. Thereafter, reflectance and dispersion of the sample 310 are measured/determined based on the detected intensity of light according to wavelengths (S220).

A multilayer structure of the sample 310 may be inspected using the measured reflectance and dispersion of the sample 310 as described above. For example, the thickness of each layer of the multilayer structure in the sample 310 may be measured or a defect thereof may be detected by comparing the measured reflectance and dispersion of the sample 310 to reflectance and dispersion calculated through simulations, and then analyzing the comparison result. Alternatively, the multilayer structure in the sample 310 may be inspected using the measured reflectance and dispersion of the sample 310 and a database in which data about reflectance and dispersion is accumulated.

Referring to FIG. 12, initially, operations from an operation of generating a multi-wavelength beam by the light source 110 (S110) to an operation of determining whether the blocker 410 is turned on or off (S150) are performed in a way similar to or the same as the ones described above in relation to FIG. 11.

Thereafter, when the blocker 410 is turned on, the first reflected beam Rp1 is generated by the sample 310 (S180), and the first reflected beam Rp1 is imaged by the second imaging optics 340 (S185). Otherwise, when the blocker 410 is turned off, the second reflected beam Rp2 is generated by the reference mirror 420 and the first reflected beam Rp1 is generated by the sample 310 (S160), and the first reflected beam Rp1 is imaged by the second imaging optics 340 and the second reflected beam Rp2 is imaged by the third imaging optics 460 (S165). The imaging of the first reflected beam Rp1 by the second imaging optics 340 and the imaging of the second reflected beam Rp2 by the third imaging optics 460 may be optional. For example, the step S165 may be omitted in certain embodiments. The beam splitter 200 generates an interfered beam by superposing the first and second reflected beams Rp1 and Rp2 (S170). The interfered beam may be incident on the second polarizer 510.

Then, the second polarizer 510 transmits only a set/predetermined polarized component of the first reflected beam Rp1 or the interfered beam of the first and second reflected beams Rp1 and Rp2 (S190), and the first imaging optics 540 images the beam transmitted through the second polarizer 510 (S205). The first imaging optics 540 forms an image of the beam provided from the second polarizer 510 on the detector 530, and the detector 530 detects the intensity of light based on the formed image (S210b). Subsequently, reflectance and dispersion of the sample 310 are measured based on the detected intensity of light according to wavelengths based on the image (S220), and a multilayer structure of the sample 310 is inspected using the measured reflectance and dispersion of the sample 310.

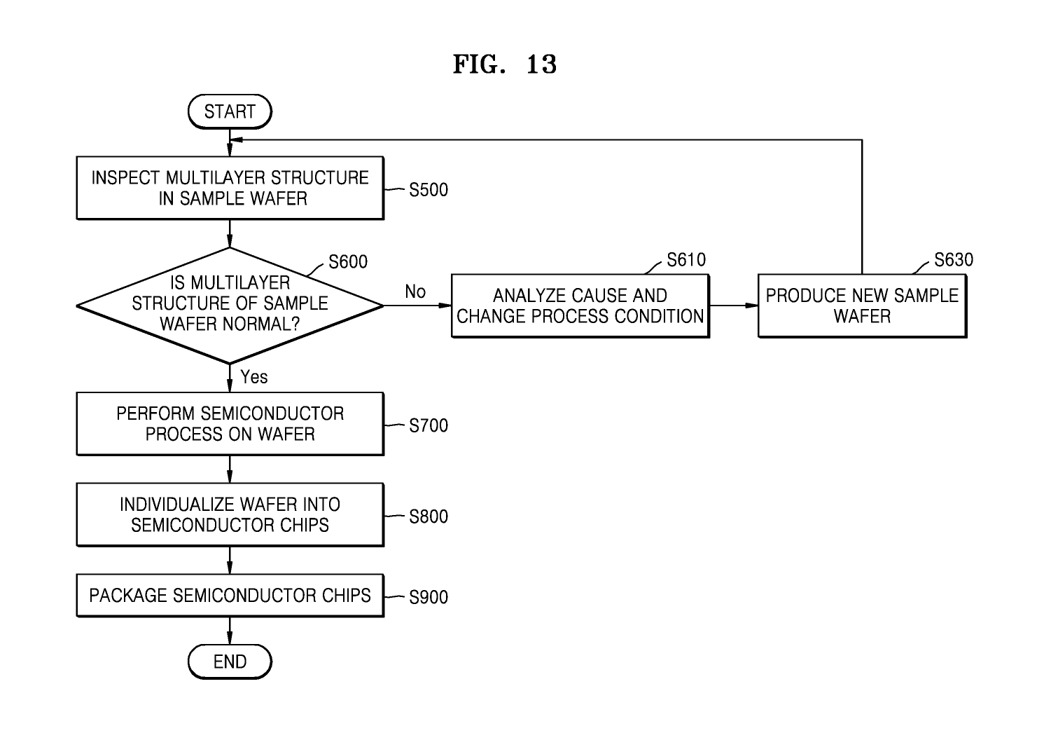

FIG. 13 is a flowchart of a semiconductor device fabricating method using a multilayer structure inspection method, according to an embodiment of the inventive concept. The descriptions given above in relation to FIGS. 10 to 12 may be applied to similar or the same elements of the present embodiment, and will be briefly provided or omitted herein.

Referring to FIG. 13, initially, a multilayer structure in a sample wafer is inspected (S500). The multilayer structure may be inspected using one of the multilayer structure inspection methods described above in relation to FIGS. 10 to 12. Herein, the sample wafer may be a sample 310 of one of the previous embodiments. For example, a sample wafer may be used as a sample of a multilayer structure inspection apparatus/method in a subsequent semiconductor device manufacturing process, e.g., using a wafer.

Then, it is determined whether the multilayer structure in the sample wafer is normal (S600). It may be determined whether the multilayer structure is normal, based on whether measured values are included in a set/predetermined reference range, whether a defect is present in a measurement region, or the like. For example, it may be determined whether the multilayer structure is normal, based on whether a measured thickness of each layer is within a set/predetermined thickness range or whether a defect is present in at least a layer within a measurement region.

When the multilayer structure in the sample wafer is normal (Yes), a semiconductor device manufacturing process is performed on a wafer (S700). The semiconductor device manufacturing process performed on the wafer may include various processes. For example, the semiconductor device manufacturing process on the wafer may include a deposition process, an etching process, an ion process, and a cleaning process. Integrated circuits and wires required for a semiconductor device may be formed by performing the semiconductor device manufacturing process on the wafer. The semiconductor device manufacturing process performed on the wafer may include a process of testing the semiconductor device of a wafer level. During the semiconductor device manufacturing process on the wafer, when inspection of a multilayer structure therein is performed in a corresponding process, the sample wafer may be selected again and the determining of whether the multilayer structure is normal (S500) may be performed.

When semiconductor devices (or circuits) are completed in the wafer by the semiconductor device manufacturing process, the wafer is divided into separate semiconductor chips (S800). The wafer may be divided into the semiconductor chips by a sawing process using a blade or a laser.

Thereafter, a packaging process is performed on the semiconductor chips (S900). The packaging process may be a process of mounting the semiconductor chips on a printed circuit board (PCB) and encapsulating the semiconductor chips with an encapsulant. The packaging process may include a process of forming a stack package by stacking a plurality of semiconductor chips on a PCB in multiple layers, or a process of forming a package on package (POP) structure by stacking a stack package on another stack package. A semiconductor device or a semiconductor package may be fabricated by the packaging process of the semiconductor chips. The semiconductor package may be tested after the packaging process.

Otherwise, when the multilayer structure in the sample wafer is abnormal (No), for example, when the thickness of each layer in the multilayer structure exceeds (or is outside of) a reference range or when a defect is present in the multilayer structure, a cause thereof is analyzed and a process condition may be appropriately changed (S610). Then, a new sample wafer may be produced based on the new process condition (S630). The new sample wafer is inserted into a multilayer structure inspection apparatus and the determining of whether the multilayer structure is normal (S500) is performed again.

While the inventive concept has been particularly shown and described with reference to embodiments thereof, it will be understood that various changes in form and details may be made therein without departing from the spirit and scope of the following claims.

1. A multilayer structure inspection apparatus comprising:
an input unit configured to generate a polarized beam;
a beam splitter configured to split the polarized beam provided from the input unit, into a first beam and a second beam;
a sample unit comprising a stage configured to support a sample and configured to provide, to the beam splitter, a first reflected beam generated by reflecting the first beam off the sample;
a reference unit comprising a reference mirror and configured to provide, to the beam splitter, a second reflected beam generated by reflecting the second beam off the reference mirror; and
a detecting unit configured to detect an intensity of light according to wavelengths by receiving a predetermined polarized component of the first reflected beam or a superposed beam of the first and second reflected beams, the first reflected beam and the superposed beam transmitted through the beam splitter,
wherein the multilayer structure inspection apparatus is configured to inspect a multilayer structure of the sample by measuring reflectance and dispersion based on the intensity of light according to wavelengths.

2. The multilayer structure inspection apparatus of claim 1, wherein the reference unit further comprises:
a blocker configured to selectively provide the second beam to the reference mirror; and
a blocker translation stage configured to turn on or off the blocker by moving the blocker.

3. The multilayer structure inspection apparatus of claim 2, wherein the multilayer structure inspection apparatus is configured so that, when the blocker is turned on, the first reflected beam is transmitted through the beam splitter while the second reflected beam is not transmitted through the beam splitter, and the multilayer structure inspection apparatus measures the intensity of the first reflected beam according to wavelengths, and
wherein the multilayer structure inspection apparatus is configured so that, when the blocker is turned off, the superposed beam of the first and second reflected beams is transmitted through the beam splitter and the multilayer structure inspection apparatus measures the dispersion according to wavelengths based on interference between the superposed first and second reflected beams.

4. The multilayer structure inspection apparatus of claim 1, wherein the stage of the sample unit is a sample translation stage configured to move the sample mounted thereon, and
wherein the multilayer structure inspection apparatus is configured so that, when the superposed beam is transmitted through the beam splitter, the first reflected beam is generated while the sample moves with the sample translation stage.

5. The multilayer structure inspection apparatus of claim 4, wherein the multilayer structure inspection apparatus is configured so that a reference sample, instead of the sample, is mounted on the sample translation stage, and
wherein the multilayer structure inspection apparatus is configured so that at least one of diagnosis of a state of the multilayer structure inspection apparatus, calibration of a measured spectrum, and compensation of a reference value is performed using the reference sample.

6. The multilayer structure inspection apparatus of claim 1, wherein the multilayer structure inspection apparatus is configured to diversify measurement variables for the reflectance and dispersion by changing the predetermined polarized component.

7. The multilayer structure inspection apparatus of claim 1, wherein the multilayer structure inspection apparatus is configured to inspect the multilayer structure of the sample by using one or a combination of the measured reflectance and dispersion.

8. The multilayer structure inspection apparatus of claim 7, wherein the multilayer structure inspection apparatus is configured so that the multilayer structure of the sample is inspected by measuring a thickness of each layer of the multilayer structure in the sample, or by detecting a defect of at least one layer of the multilayer structure, and
wherein the multilayer structure inspection apparatus is configured to measure the thickness or detect the defect by comparing the measured reflectance and dispersion to reflectance and dispersion information calculated through simulations.

9. The multilayer structure inspection apparatus of claim 1, wherein the input unit comprises:
a light source configured to generate a multi-wavelength beam;
a collimator configured to collimate the beam provided from the light source, into a parallel beam; and
a first polarizer configured to polarize the beam provided from the collimator, and
wherein the detecting unit comprises:
a second polarizer configured to transmit the predetermined polarized component of the first reflected beam or the superposed beam of the first and second reflected beams;
a spectrometer configured to split the beam provided from the second polarizer, according to wavelengths; and
a detector configured to detect an intensity of light according to wavelengths from the spectrometer.

10. The multilayer structure inspection apparatus of claim 1, wherein the input unit comprises:
a light source configured to generate a multi-wavelength beam;
a monochromator configured to convert the multi-wavelength beam into a monochromatic beam;
a collimator configured to collimate the beam provided from the monochromator into a parallel beam; and
a first polarizer configured to polarize the beam provided from the collimator, and
wherein the detecting unit comprises:
a second polarizer configured to transmit the predetermined polarized component of the first reflected beam or the superposed beam of the first and second reflected beams; and
a detector configured to detect an intensity of light according to wavelengths from the second polarizer.

11. The multilayer structure inspection apparatus of claim 10, further comprising imaging optics disposed in at least one of the following locations: between the stage of the sample unit and the beam splitter, between the reference mirror of the reference unit and the beam splitter, and between the second polarizer and the detector.

12. A multilayer structure inspection apparatus comprising:
a multi-wavelength light source;
a collimator configured to collimate a beam provided from the multi-wavelength light source into a parallel beam;
a first polarizer configured to polarize the beam provided from the collimator;
a beam splitter configured to split the beam provided from the first polarizer, into a first beam and a second beam;
a sample unit comprising a sample translation stage configured to support a sample having a multilayer structure, the sample unit configured to provide, to the beam splitter, a first reflected beam generated by reflecting the first beam off the sample;
a reference unit comprising a reference mirror, the reference unit configured to provide, to the beam splitter, a second reflected beam generated by reflecting the second beam off the reference mirror;
a second polarizer configured to transmit a predetermined polarized component of the first reflected beam or a superposed beam of the first and second reflected beams, the first reflected beam and the superposed beam transmitted through the beam splitter;
a spectrometer configured to split the beam provided from the second polarizer, according to wavelengths; and
a detector configured to detect an intensity of light according to wavelengths from the spectrometer,
wherein the sample translation stage is configured to move the sample mounted thereon,
wherein the reference unit further comprises:
a blocker configured to selectively provide the second beam to the reference mirror; and
a blocker translation stage configured to turn on or off the blocker by moving the blocker, and
wherein the multilayer structure inspection apparatus is configured to inspect the sample by measuring reflectance and dispersion based on the intensity of light according to wavelengths.

13. The multilayer structure inspection apparatus of claim 12, wherein the multilayer structure inspection apparatus is configured so that, when the blocker is turned on, the multilayer structure inspection apparatus measures the intensity of the first reflected beam according to wavelengths, and
wherein the multilayer structure inspection apparatus is configured so that, when the blocker is turned off, the multilayer structure inspection apparatus measures the dispersion according to wavelengths based on interference between the superposed first and second reflected beams.

14. A multilayer structure inspection apparatus comprising:
a multi-wavelength light source;
a monochromator configured to convert a beam provided from the multi-wavelength light source into a monochromatic beam;
a collimator configured to collimate the monochromatic beam provided from the monochromator into a parallel beam;
a first polarizer configured to polarize the parallel beam provided from the collimator;
a beam splitter configured to split the polarized beam provided from the first polarizer, into a first beam and a second beam;
a sample unit comprising a sample translation stage configured to support a sample having a multilayer structure, the sample unit configured to provide, to the beam splitter, a first reflected beam generated by reflecting the first beam off the sample;
a reference unit comprising a reference mirror, the reference unit configured to provide, to the beam splitter, a second reflected beam generated by reflecting the second beam off the reference mirror;
a second polarizer configured to transmit a predetermined polarized component of the first reflected beam or a superposed beam of the first and second reflected beams, the first reflected beam and the superposed beam transmitted through the beam splitter; and
a detector configured to detect an intensity of the beam transmitted from the second polarizer,
wherein the sample translation stage is configured to move the sample mounted thereon,
wherein the reference unit further comprises:
a blocker configured to selectively provide the second beam to the reference mirror; and
a blocker translation stage configured to turn on or off the blocker by moving the blocker, and
wherein the multilayer structure inspection apparatus is configured to inspect the sample by measuring reflectance and dispersion based on the intensity of the beam transmitted from the second polarizer according to wavelengths.

15. The multilayer structure inspection apparatus of claim 14, wherein the multilayer structure inspection apparatus is configured so that, when the blocker is turned on, the multilayer structure inspection apparatus measures the intensity of the first reflected beam according to wavelengths, and
wherein the multilayer structure inspection apparatus is configured so that, when the blocker is turned off, the multilayer structure inspection apparatus measures the dispersion according to wavelengths based on interference between the superposed first and second reflected beams.

16. The multilayer structure inspection apparatus of claim 14, further comprising imaging optics disposed in at least one of the following locations: between the sample translation stage of the sample unit and the beam splitter, between the reference mirror of the reference unit and the beam splitter, and between the second polarizer and the detector.

17-28. (canceled)
